(19) United States
(12) Patent Application Publication
(10) Pub. No.: US 2012/0015471 A1
(43) Pub. Date: Jan. 19, 2012

(54) MULTIPLE-PATH LASER EDGE DELETE PROCESS FOR THIN-FILM SOLAR MODULES

(75) Inventors: LI-PING WANG, Fremont, CA (US); Tzay-Fa Su, San Jose, CA (US); Sarin Sundar Jainnagar Kuppuswamy, Hyderabad (IN); Ole Luckner, Dresden (DE)

(73) Assignee: APPLIED MATERIALS, INC., Santa Clara, CA (US)

(21) Appl. No.: 13/181,401

(22) Filed: Jul. 12, 2011

Related U.S. Application Data
(60) Provisional application No. 61/364,338, filed on Jul. 14, 2010.

(51) Int. Cl. H01L 31/18

(52) U.S. Cl. 438/73; 257/E31.11

(57) ABSTRACT

Embodiments of the present invention provide methods for edge film stack removal for use in fabricating photovoltaic devices. In one embodiment, the method includes providing a substrate having a film stack deposited thereon, the film stack comprising a transparent conductive layer, a silicon-containing layer, and a metal back contact layer, removing the metal back contact layer and the silicon-containing layer formed on a periphery region along a side of the substrate using an electromagnetic radiation delivered at a first energy level, and removing the transparent conductive layer formed on the periphery region along the side of the substrate using electromagnetic radiation delivered at a second energy level that is higher than the first energy level.

### CROSS-REFERENCE TO RELATED APPLICATIONS

This application claims benefit of U.S. provisional patent application Ser. No. 61/364,338, filed Jul. 14, 2010, which is herein incorporated by reference.

### BACKGROUND OF THE DISCLOSURE

1. Field of the Invention

The present invention relates to methods for an edge film removal process, more particularly, for an edge film removal process for fabricating photovoltaic devices.

2. Description of the Background Art

Photovoltaic (PV) devices or solar cells are devices which convert sunlight into direct current (DC) electrical power. Typically, a thin film solar cell includes a photoelectric conversion unit and a transparent conductive layer. The transparent conductive layer is disposed as a front electrode on the bottom of the solar cell in contact with a glass substrate and/or as a back surface electrode on the top of the solar cell. The photoelectric conversion unit may include a p-type silicon layer, a n-type silicon layer and an intrinsic type (i-type) silicon layer sandwiched between the p-type and n-type silicon layers. When the p-i-n junction of the PV cell is exposed to sunlight (consisting of energy from photons), the sunlight is directly converted to electricity through a PV effect.

During deposition, the material being deposited may deposit on, and over, the edge of a substrate, resulting in an electrical connection, or “short”, between the two transparent conductive layers. Therefore, the continuity of material from the front to the back, over the side of the substrate, must be broken to eliminate the short. In some cases, a shadow mask or edge ring may be used to mask the edge from the depositing material, but this can result in non-uniform deposition at the substrate edge regions, as compared to other layers deposited without such masks or using overlying frames having a different alignment with respect to the substrate edge as compared to the shadow frame. Additionally, material along the edge of the substrate, which if left intact may interfere with the assembly and packaging of the cells into a solar panel frame, must also be removed to eliminate interference or other potential issues during assembly into a frame.

In conventional edge isolation techniques, material removal with a diamond impregnated belt or with a grinding wheel is typically used to mechanically grind unwanted edge residuals or deposited materials from the periphery regions of the substrate. However, these techniques often result in incomplete material removal on the substrate edge, as well as scratches or even substrate damage such as micro cracks at the substrate edge. Alternatively, a thermal ablation process using a single-pass, high-energy laser has been used by the industry to remove unwanted materials from the substrate periphery region with better throughput than mechanical removal approaches without leaving scratches or micro cracks at the substrate edge. However, with a larger number of thin film layers as used in a tandem junction design, it has been reported that the conventional single-pass laser edge removal process may still leave powder residues and visible debris at the periphery region of the substrate, which may impact long-term cell and power reliability. Thus, a higher energy laser may be needed to ablate the thicker tandem junction, but the use of a high-energy laser for removing thicker film stacks at the periphery region of the tandem junction solar cell may damage the glass substrate or change film properties of the transparent conductive film when passing therethrough. Furthermore, it has been also found that the high-energy laser would inevitably melt the back metal contact layer and the silicon-containing film stack deposited on the transparent conductive film and form an unwanted alloy that is difficult to remove.

Therefore, there is a need for an improved laser edge removal process for effectively removing film materials from the periphery region of solar cells without having issues as discussed above.

### SUMMARY OF THE INVENTION

The present invention provides methods for edge film stack removal for use in fabricating photovoltaic devices. In one embodiment, a method for processing solar cell devices on a substrate includes providing a substrate having a film stack deposited thereon, the film stack comprising a transparent conductive layer, a silicon-containing layer, and an electrically conductive layer, removing the electrically conductive layer and the silicon-containing layer formed on a periphery region along a side of the substrate using an electromagnetic radiation delivered at a first energy level, and removing the transparent conductive layer formed on the periphery region along the side of the substrate using electromagnetic radiation delivered at a second energy level that is higher than the first energy level.

In another embodiment, a method for processing solar cell devices on a substrate includes providing a substrate having a transparent conductive layer and a film stack deposited over the transparent conductive layer, the film stack comprising one or more silicon-containing layers and an electrically conductive layer, removing the film stack from a periphery region along a side of the substrate during a first scan of an electromagnetic radiation line delivered at a first power level, and removing the transparent conductive layer from the periphery region along the side of the substrate during a second scan of the electromagnetic radiation line delivered at a second power level that is different from the first power level.

In yet another embodiment, a method for processing solar cell devices on a substrate includes providing a substrate having a transparent conductive layer and a film stack sequentially deposited thereon, the film stack comprising one or more silicon-containing layers and an electrically conductive layer, directing a series of sequential laser pulses delivered at a first pulse energy across a periphery region along a side of the substrate to remove the film stack, and directing a series of sequential laser pulses delivered at a second pulse energy across the periphery region along the side of the substrate to remove the transparent conductive layer, wherein first pulse energy is lower than the second pulse energy.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a partial flow diagram for manufacturing solar cell devices on a substrate;

FIG. 2A depicts a top view of the substrate prior to processing in the laser edge removal tool;

FIG. 2B depicts a cross-sectional view of a substrate with solar cell devices and residual films formed in the periphery region of the substrate;

FIG. 3 depicts a side view of a laser edge removal tool that may be utilized to remove films from the periphery region of the substrate; and

FIG. 4 depicts a cross-sectional view of a periphery region of a substrate on which a laser edge removal process has been performed.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention provide methods for edge film stack removal process for fabricating photovoltaic devices. Particularly, the present invention provides a multi-pass laser edge removal process for thin film solar devices which typically include a front electrode layer, a silicon-containing film stack, and a metal back electrode layer that are sequentially deposited over the substrate. The multi-pass laser edge removal process may include a first laser pass using a lower power energy directed to remove the metal back electrode layer and the silicon-containing film stack, and a second laser pass using a higher power energy directed to remove the front electrode layer (e.g., a TCO layer). The energy used for the first laser pass is relatively low so that it will not melt the metal back electrode layer and the silicon-containing film stack on the back and/or change film properties of the front electrode layer when passing through the front electrode layer. The present invention advantageously increases clearness and accuracy of removing film stacks at a periphery region along a side of a substrate without having issues with residue powders or formation of unwanted alloys due to melting of the back metal contact and silicon-containing materials, thereby providing a good seal surface for the substrate to facilitate subsequent bonding and packaging processes and eliminating shorts across the active energy converting region of the substrate.

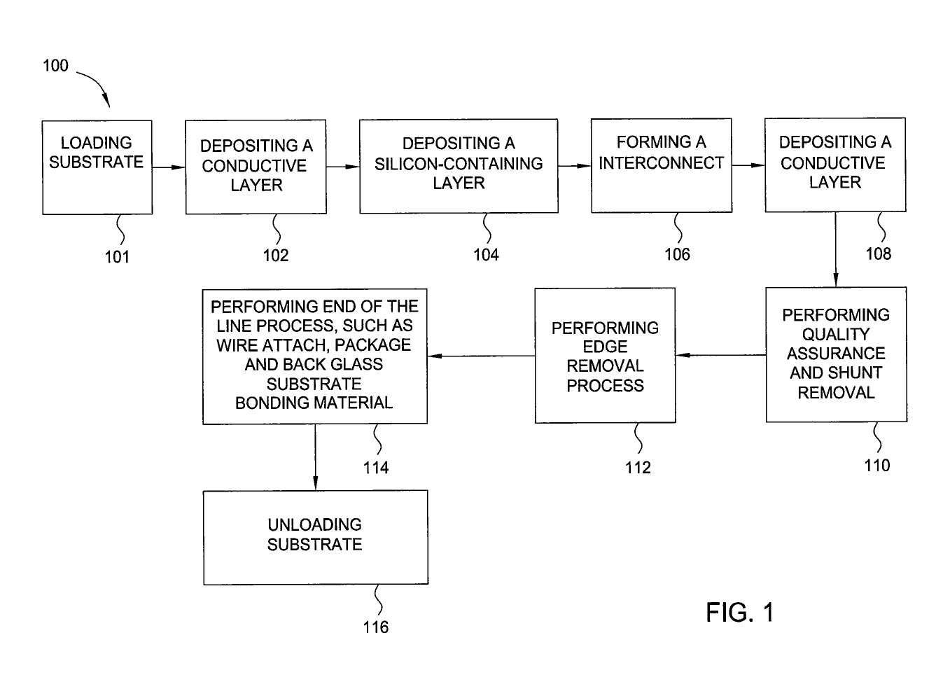

FIG. 1 depicts a process sequence 100 for manufacturing solar cell devices on a substrate. The process sequence 100 may include a plurality of process steps performed in different processing modules and automation equipment for manufacturing the solar cell devices. It is noted that FIG. 1 only depicts a portion of the process steps performed during the manufacture of solar cell devices. The configurations, number of processing steps, or order of the processing steps in the process sequence 100 is exemplary, and not intended to limit the scope of the invention described herein. Some other process steps of the process sequence are known to those skilled in the art and eliminated for sake of brevity. One suitable example of the overall process sequence is disclosed in detail by U.S. application Ser. No. 12/202,199, filed Aug. 29, 2008 by Bachrach et al., titled “Photovoltaic Production Line”, and is incorporated herein by reference.

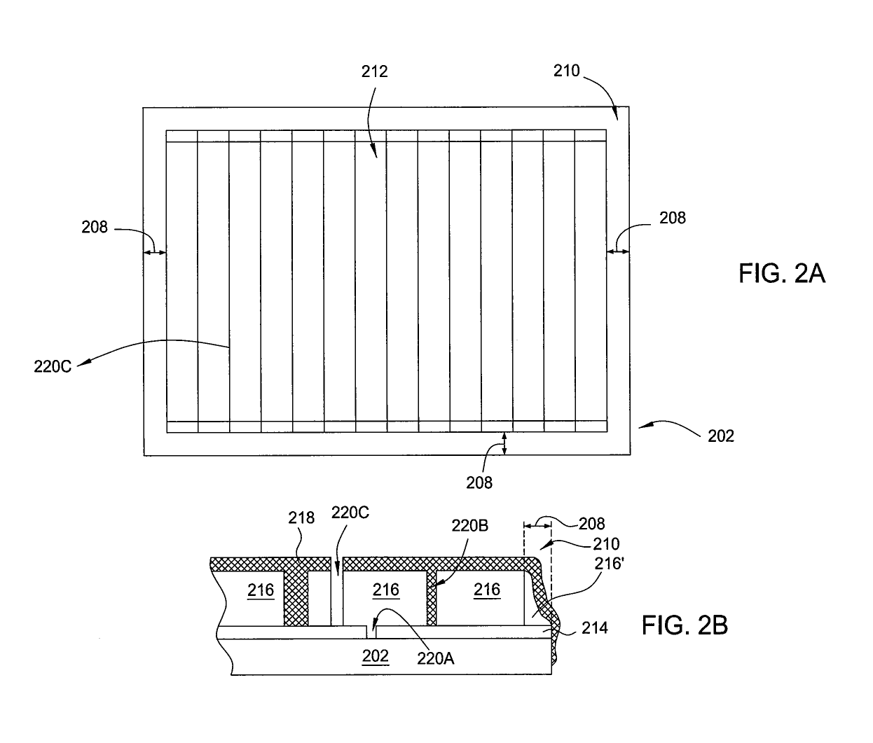

As shown in FIG. 1, a process sequence 100 starts at step 101 by loading a substrate into a solar cell production line. The production line may include a plurality of processing tools and automation equipment to facilitate fabricating the solar cells on the substrate. FIG. 2B is completion of a solar cell device showing the layers formed thereon. The sequence will be described below with reference to steps shown in FIG. 1 and layers shown in FIG. 2B. At step 102, a first transparent conductive oxide (TCO) layer 214, which may serve as a front electrode in the solar cell device, is deposited on the substrate 202 in a deposition chamber such as a PVD chamber. The first TCO layer 214 has scribed therein a pattern of first scribe lines 220A (only one is shown). The first TCO layer 214 may be a zinc containing material, aluminum containing material, tin containing material, ITO containing material, alloys thereof, or any other suitable conductive materials such as cadmium stannate. In one example, the first TCO layer 214 is a metal oxide such as tin oxide, zinc oxide, indium tin oxide, or combinations thereof. The first TCO layer 214 may also include additional dopants and components. For example, the zinc oxide may further include dopants that are selected from a group consisting of aluminum containing materials, boron containing materials, titanium containing materials, tantalum containing materials, tungsten containing materials, alloys thereof, combinations thereof, gallium, or other suitable dopants, depending upon the application.

At step 104, a silicon-containing film layer 216 is deposited over the first TCO layer 214 as shown in FIG. 2B to produce the active, energy converting portion of the solar cell. The silicon-containing film layer 216 may be a film stack including a p-type silicon containing layer, a n-type silicon containing layer, and an intrinsic type (i-type) silicon containing layer sandwiched between the p-type and n-type silicon containing layers. Multiple layers may be formed in the silicon-containing film layer 216 for different process purposes. For example, multiple silicon-based layers of n-i-p, p-i-n, n-p or p-n layers may be used in the silicon-containing film layer 216 to provide one or more, e.g., multiple, junctions to improve light conversion efficiency. Suitable examples of the silicon-containing film stack are disclosed in U.S. application Ser. No. 11/624,677, filed Jan. 18, 2007 by Choi et al, titled “Multi-Junctions Solar Cells and Methods and Apparatus for Forming the Same”, U.S. application Ser. No. 12/208,478, filed Sep. 11, 2008 by Sheng et al, titled “Microcrystalline Silicon Alloys for Thin Film and Wafer Based Solar Applications”, and are herein incorporated by reference.

At step 106, an interconnect formation process is performed to form an interconnect, such as second scribing lines 220B, in the silicon-containing film layer 216 as shown in FIG. 2B. The interconnect formation process is performed to electrically isolate various regions on the substrate of the solar cell from each other by a laser ablation process using, for example, a Nd:vanadate (Nd:YVO₄) laser source. It is noted that the interconnect formation process can be performed during different stages of the process sequence 100 to form different scribing lines 220A, 220B, 220C that electrically isolate adjacent solar cells.

At step 108, a metal back contact layer 218 is deposited over the silicon-containing film layer(s) 216 as shown in FIG. 2B, or optionally deposited over a second transparent conductive oxide (TCO) layer (not shown) which may be similar to the first TCO layer 214 and serves as a back electrode. The metal back contact layer 218 may include, but is not limited to, a material selected from the group consisting of Al, Ag, Ti, Cr, Au, Cu, Pt, alloys thereof, or combinations thereof. After depositing the metal back contact layer 218, a pattern of third scribe lines 220C is formed through the metal back contact layer 218 and the silicon-containing film layer 216, thereby electrically connecting the back metal contact layer 218 through the silicon-containing film layer 216 to the front electrode (i.e., the TCO layer 214) of the adjacent cells. While not mentioned here, other films or materials may be provided over metal back layer 218 to complete the solar cell. The solar cells may be interconnected to form modules, which in turn can be connected to form arrays for a higher performance.

At step 110, an optional quality assurance and/or shunt removal process may be performed on the substrate 202 to assure that the devices formed on the substrate surface meet a desired quality standard and in some cases correct defects in the formed devices. During the testing process, a probing device is used to measure the quality and material properties of the formed solar cell device by use of one or more substrate contacting probes. In one embodiment, the quality assurance testing tool projects a low level of light at the p-i-n junction(s) of the solar cell and uses the one more probes to measure the output of the cell to determine the electrical characteristics of the formed solar cell device(s). If the module detects a defect in the formed device, corrective action may be taken to fix the defects. For example, if a short or other similar defect is found, it may be desirable to create a reverse bias between regions on the substrate surface to control and/or correct one or more of the defectively formed regions of the solar cell device. The reverse bias generally delivers a high voltage sufficient to cause the conductive elements in areas between the isolated regions to change phase, decompose or become altered in a way that eliminates or reduces the magnitude of the electrical short, thereby correcting the defects in the solar cells.

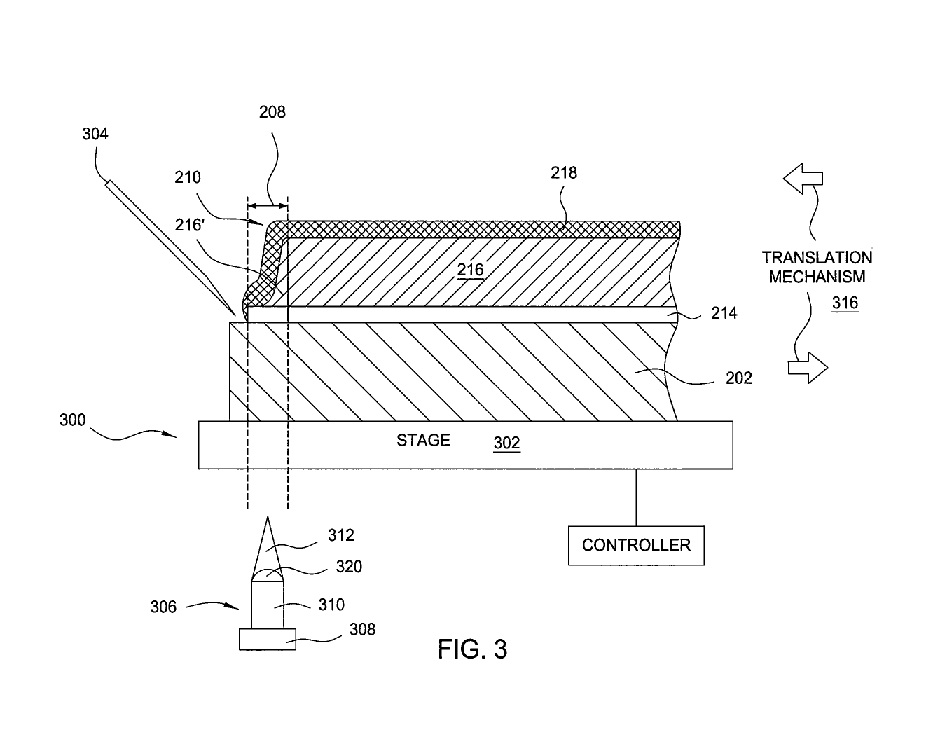

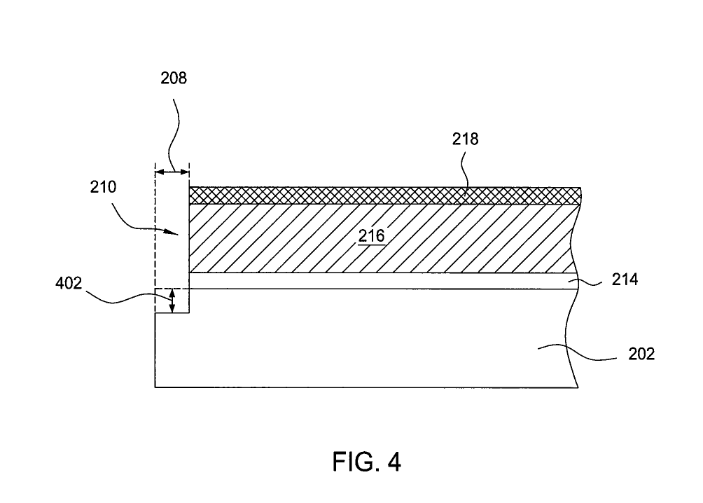

At step 112, after the optional quality assurance and/or shunt removal process, the substrate 202 is transferred to a laser edge removal tool to remove a portion of the film stack formed at the periphery region of the substrate 202. The substrate 202 is positioned in the laser edge removal tool to remove a portion of the film stack along the edge of the substrate to reduce the likelihood of damage, such as clipping or particle generation, from occurring during subsequent processing. Additionally, removal of the edge portion of the film stack may also leave the periphery region of the substrate 202 free of materials which can be utilized later for a frame holding area to facilitate bonding or sealing the substrate 202 to a backside of another substrate to complete the solar cell module assembly. The laser edge removal process in accordance with the present invention will be discussed in detail below in conjunction with FIGS. 3 and 4.

At step 114, end of the line processes are performed on the substrate 202. End of the line processes may include final wire attaching, bonding, packaging, and backside substrate bonding processes. At step 116, after the support structure, wiring structures, or framing structures are formed on the substrate, the substrate 202 is removed from the production line and the solar cell fabrication process is completed. It is noted that some other steps may be performed in between each steps to manufacture the devices. The process sequence 100 only provides an exemplary process sequence that includes only a portion of some major process steps to manufacture the devices. It is contemplated that other process sequences associated with the solar cell device fabrication may also be adapted to use the laser edge removal process of the present invention as will be descried below.

FIG. 2A is a top view of the substrate 202 prior to processing in the laser edge removal tool at step 112. As discussed above, after layers of deposition, the periphery region 210 of the substrate 202 may have a different film stack thickness than the thickness of the film stack in the cell integrated region 212. In certain cases, the periphery region 210 may have a width 208 ranging between about 8 mm and about 15 mm, such as about 12 mm, from the substrate edge. As discussed above, when forming different layers on the substrate utilizing different tools, a mismatch in the film thickness may result at the periphery region 210 of the substrate 202 due to the use of the shadow mask during the silicon-containing film stack deposition that would cause the substrate periphery region 210 to be free of the silicon-containing film layer 216. This is because the shadow frame may not fully cover the periphery region 210 even if with the shadow frame, or the silicon-containing film layer 216 may accidentally accumulate or deposit on a portion of the first TCO layer 214, resulting in the silicon-containing film layer 216′ partially deposited on the periphery region 210. Therefore, the film thickness at the periphery region 210 may include the thickness of the first TCO layer 214 and the metal back contact layer 218, and a portion of the silicon-containing film layer 216′ sandwiched between the first TCO layer 214 and the metal back contact layer 218 from the side, as shown in FIG. 2B. In order to remove the residual films formed in the periphery region 210 of the substrate 202, the substrate 202 is further transferred to the laser edge removal tool as discussed above at step 112 to remove unwanted films in the periphery region 210 using the inventive laser edge removal process discussed below in conjunction with FIG. 3.

FIG. 3 shows a side view of an exemplary laser edge removal tool 300 that may be used to remove one or more of films from the periphery region 210 of the substrate 202. The laser edge removal tool 300 generally includes a wave electromagnetic radiation module 306, a stage 302 configured to receive and maneuver the substrate 202 disposed thereon, and a translation mechanism 316. In one embodiment, the wave electromagnetic radiation module 306 is positioned beneath the substrate 202 and opposite an exhaust mechanism or particle collector 304 used for extracting material ablated or otherwise removed from the substrate during the process. In another embodiment, the wave electromagnetic radiation module 306 may be positioned above the substrate 202 to ablate the film stack at the periphery region 210 of the substrate 202 from the top. Alternatively, the wave electromagnetic radiation module 306 may be positioned beneath the substrate 202 while flipping the substrate 202 during the laser edge removal process.

The wave electromagnetic radiation module 306 comprises a wave electromagnetic radiation source 308 and focusing optics 310 disposed between the wave electromagnetic radiation source 308 and the stage 302. In one embodiment, the wave electromagnetic radiation source 308 may be an infrared (IR) laser beam source, a Nd:YAG or Nd:YVO₄ laser beam source, crystalline disk laser source, fiber-diode (fiber laser) or other suitable laser beam source that can provide and emit a pulsed or continuous wave of radiation at a wavelength between about 1030 nm and about 1070 nm, such as about 1064 nm, to ablate materials from the substrate surface. In another embodiment, the wave electromagnetic radiation source 308 may include multiple laser diodes, each of which produces uniform and spatially coherent light at the same or desired wavelength. The power of the laser diode/s is in the range of about 100 Watts to about 1000 Watts.

The focusing optics 310 may include one or more collimators to collimate radiation from the wave electromagnetic radiation source 308 into a substantially parallel beam. This collimated radiation beam is then focused by at least one lens 320 into a line of radiation 312 directed at the periphery region 210 of the substrate 202. Alternatively, a beam profiler (not shown) may be used where scanners are used, allowing for calibration of the beam and/or adjustment of beam position. The radiation 312 is focused on the periphery region 210 along the side of the substrate 202 to remove the film stack from the periphery region 210. The radiation 312 emitted from radiation source 308 may scan around each side of the substrate 202 as many times as needed, or using the inventive laser edge removal process described below, until the film stack has been completely removed.

Lens 320 may be any suitable lens, or series of lenses, capable of focusing radiation into a line or spot. In one embodiment, lens 320 is a cylindrical lens. Alternatively, lens 320 may be one or more concave lenses, convex lenses, plane mirrors, concave mirrors, convex mirrors, refractive lenses, diffractive lenses, Fresnel lenses, gradient index lenses, or the like.

A particle collector 304 may be disposed adjacent to the periphery region 210 of the substrate, depending upon the location of the wave electromagnetic radiation module 306. During laser cutting, the material being removed may be drawn to the particle collector 304 to maintain cleanness of the tool 300. The stage 302 can be any platform or chuck capable of securely holding the substrate 202 during transmission. In one aspect, the stage 302 includes a means for grasping the substrate, such as a frictional, vacuum, gravitational, mechanical, or electrical system. Examples of suitable means for grasping may include, but are not limited to, mechanical clamps, electrostatic or vacuum chucks, or the like.

The laser edge removal tool 300 may include a translation mechanism 316 configured to translate the stage 302 and the line of radiation 312 relative to one another. In one embodiment, the translation mechanism 316 is coupled to the stage 302 to move the stage 302 relative to the wave electromagnetic radiation source 308 and/or the focusing optics 310. In another embodiment, the translation mechanism 316 is coupled to the wave electromagnetic radiation source 308 and/or the focusing optics 310 to move the wave electromagnetic radiation source 308 and/or the focusing optics 310 relative to the stage 302. In yet another embodiment, the translation mechanism 316 moves both the wave electromagnetic radiation source 312 and/or the focusing optics 310, and the stage 302. However, any suitable translation mechanism may be used, such as a conveyor system, rack and pinion system, or an x/y actuator, a robot, or other suitable mechanism.

The translation mechanism 316 may be coupled to a controller to control the scan speed at which the stage 302 upon which substrate 202 is supported and the line of radiation 312 move relative to one another. Translation of the stage 302 and the line of radiation 312 relative to one another may be configured to be along the periphery region 210 of the substrate 202 to focus on removing the films on the substrate edge without damage to other regions of the substrate 202. In one example, the translation mechanism 316 moves at a constant speed, of approximately 1000 centimeters per second (cm/s) for a 10 mm to 20 nm wide line, for example, similar to the width 208 of the periphery region 210 of the substrate 202. The translation of the stage 302 and the line of radiation 312 relative to one another may be moved with other paths as desired.

The laser edge removal process, as will be discussed below, removes unwanted film stack at the periphery region 210 of the substrate 202 and ensures the cleanliness of the substrate periphery region to facilitate the subsequent frame bonding process.

### Laser Edge Removal Process

During the laser edge removal process, the line of radiation 312 emitted from the wave electromagnetic radiation source 308 is controlled to adjust a position of the “spot” of the radiation beam within a scribing field in the periphery region 210 of the substrate 202. Depending upon the application, a spot size directed on the substrate 202 may be on the order of microns, such as 1 mm² within a scanning field of approximately 60 mm×60 mm, although various other dimensions are possible depending upon the process regime. “Scanning filed” is defined as the length of travel of the focused radiation beam in one dimension parallel to the direction of travel of the sweeping beam. By controlling a size and position of the scanning field relative to the substrate 202, the beams (e.g., lasers) are able to effectively ablate off materials at any location on the substrate 202 while making a minimal number of passes over the substrate 202. The substrate 202 may be moved relative to the wave electromagnetic radiation source 308 in either a transverse (Y) direction or a longitudinal (X) direction using any conventional approach as discussed above. For example, if the substrate 202 is moved in a longitudinal direction, the wave electromagnetic radiation module 306 may direct the radiation 312 in the longitudinal, but opposite direction to the substrate, to form portions or segments of scribe lines within the scanning field along the periphery region 210 of the substrate 202. In such a case, the substrate 202 may be supported and transported by the stage 302 configured to slide within a processing chamber using, for example, the translation mechanism 316 as discussed above. The stage 302 may be configured to move the substrate 202 in a desired direction along with the wave electromagnetic radiation module 306. Alternatively, the stage 302 may be held stationary and the wave electromagnetic radiation module 306 is controlled to move in a desired direction or pattern relative to the stage 302. If desired, the stage 302 and the wave electromagnetic radiation module 306 may be both controlled so as to be movable relative to one another during the laser edge removal process.

During the laser edge removal process, a pulse of radiation 312 is directed through a substantially transparent substrate 202, such as glass in one exemplary embodiment, to a desired location or depth in one or more of the films to be ablated. In various embodiments, the radiation 312 may be a pulsed, Q-switched fiber laser operating at a frequency of about 30 kHz to about 150 kHz and at a wavelength on the order of about 266 nm, 532 nm, or 1064 nm. The layers of material to be ablated, such as the metal back contact layer 218, a portion of the silicon-containing film layer 216′ sandwiched between the first TCO layer 214 and the back metal contact layer 218, and the first TCO layer 214 (FIG. 2B), are on the opposite side of the substrate 202 from the laser, such that the laser pulses pass through the substrate 202 and ablate the layer(s) on the opposite side, thus causing the exposed material to ablate up and away from the substrate 202, which can be extracted by the particle collector 304 using, for example, vacuum force.

In order to remove one or more of the films in the periphery region 210 along the side of the substrate 202, a single-pass pulsed laser thermal ablation process using high pulse energy has been adapted by the industry to achieve clean material removal in the thermal ablation regime. With growing number of thin film layers in the tandem junction design, the film stack thickness is approaching about 3 microns or greater. As a result, a higher laser pulse energy is typically required to achieve clean material removal and additional manufacturing consideration such as throughput. However, it has been reported that the conventional single-pass laser edge removal on the tandem junction solar panel often leaves powder residues and visible debris, which may impact long-term product reliability. In addition, a single-pass laser may limit the amount of laser power that can be used to ablate off the materials without damaging the glass, or changing the film properties of the first TCO (transparent conductive oxide) layer 214 in the neighborhood area, the use of a stronger laser energy for removing thicker film stacks in the periphery region 210 of the substrate 202 can result in the back metal inevitably melting with the silicon-containing film layer 216′ and/or the first TCO layer 214, forming an unwanted alloy at the periphery region of the substrate which makes the resulting materials even harder to remove.

Contrary to the conventional single-pass laser edge removal process, the present inventors propose a multi-pass laser edge removal process which has proved effective in removing the film stacks in the periphery region along the side of the substrate without damaging the glass or melting the back electrode. In one embodiment, the multi-pass laser edge removal process includes a two-pass process in which a first laser pass using a relatively lower power energy is directed to remove the back metal contact layer 218 and the silicon-containing film layer 216′ sandwiched between the first TCO layer 214 and the back metal contact layer 218, and a second laser pass using a higher power energy is directed to remove the first TCO layer 214. The energy needed for the first laser pass should be sufficient to ablate two different types of layers (i.e., the back metal contact layer 218 and the silicon-containing film layer 216′) sequentially or concurrently while being low enough to prevent damage or change the properties of the first TCO layer 214 underneath.

During the first laser pass, the line of radiation 312 emitted from the wave electromagnetic radiation source 308 penetrates the substrate 202 from the bottom and focuses on the material to be ablated. A laser pulse of sufficient intensity then heats the target material layers e.g., the back metal contact layer 218 and the silicon-containing film layer 216′ rapidly and resulting in removal of the materials from the substrate 202. The materials removed from the surface of the substrate 202 are then extracted by the particle collector 304. Since the back metal and silicon film stacks inherently offer better heat absorption compared to the first TCO layer 214, the energy needed for the first laser pass can be lower and therefore will not melt the back metal contact layer 218 and the silicon-containing film layer 216′ before they can be ablated and will not change film properties of the first TCO layer 214, nor damage the glass substrate when passing through the substrate 202.

Upon removal of the back metal contact layer 218 and the silicon-containing film layer 216′, the first TCO layer 214 is exposed to air. The second laser pass is then performed to direct the line of radiation 312 at the exposed first TCO layer 214 and ablate the first TCO layer 214 from the periphery region 210 of the substrate 202. Since the first TCO layer 214 has lower heat absorption compared to the back metal and silicon film stacks and is the only material remaining in the periphery region of the substrate 202, the energy needed for the second laser pass can be higher than that of the first laser pass. While being stronger than the first laser pass, it is contemplated that the highest pulse energy of the second laser pass is still below the glass damage threshold.

The power level for first and second laser passes may be reversed or adjusted in cases where the wave electromagnetic radiation module 306 is positioned above the substrate 202. In such a case, a relatively lower pulse energy of the first laser pass may sequentially or concurrently ablate off the back metal contact layer 218 and the silicon-containing film layer 216′ from the top (i.e., opposite to the bottom of the substrate), followed by a higher pulse energy of the second laser pass removing the first TCO layer 214.

While not shown in the drawing, it is understood that the scribing line configured to remove unwanted layers during each laser pass is actually formed of a series of overlapping scribe “dots,” each being formed by a pulse of the radiation 312 directed to a particular position on the periphery region 210 along the side of the substrate 202. To ensure acceptable intensity of the ablation process, a spot of sufficient size, e.g., about 1 mm² is typically required. In order to form a continuous line, these dots must sufficiently overlap, such as by about 2% to about 30% by area, for example, between about 5% and about 20%. In cases where the periphery region 210 of the substrate has a width 208 ranging between about 8 mm and about 15 mm, such as about 12 mm, the wave electromagnetic radiation module 306 may have to make multiple passes in order to form multiple overlapping scribing lines where a portion of each scribing line is overlapped to prevent gaps. In such a case, the scribing lines may be sufficiently overlapped from each other by about 5% to about 20% by area, such as about 8% to about 15% by area, for example about 10%. The scribing lines may be overlapped in a desired pattern such as a zig-zag pattern so as to form one or more scribing segments. These scribing segments may need to be sufficiently overlapped to prevent gaps while substantially covering the periphery region 210 of the substrate. In one example where a substrate having a width of about 2.6 m and a length of about 2.2 m is used, the scribing segments may be sufficiently overlapped by about 20% to about 40%, such as about 25% to about 35% by area, for example about 30%, to effectively cover the periphery region of the substrate while maintaining a high throughput.

In various embodiments where a rectangular substrate having a width of about 2.6 m and a length of about 2.2 m is used, several scribing spots on a spot size of about 1 mm² may be overlapped at an exemplary range of overlap percentage as discussed above and moved in a desired pattern to provide a scribing segment with a length of about 70 mm and a width of about 12 mm. The size of the scribing segment may vary depending upon the type and field view of the focusing optics 310 used. For the substrate with a width or length of about 2.6 m or 2.2 m, several scribing segments may be overlapped at an exemplary range of overlap percentage as described above to properly cover the entire periphery region 210 of the substrate 202. During the laser edge removal process, a line of electromagnetic radiation 312 (FIG. 3) is directed to travel forward along the 2.6 m or 2.2 m side of the substrate with a relatively lower laser pulse energy to ablate off the back metal contact layer 218 and the silicon-containing film layer 216′, and then the line of electromagnetic radiation 312 is traveling backward (reverse direction) along the 2.6 m or 2.2 m side of the substrate with a relatively higher laser pulse energy to ablate off the TCO layer 214 from the periphery region 210 of the substrate 202. It is contemplated that the power level of the electromagnetic radiation and/or the size of the scribing segment may be adjusted as necessary to repeat the laser edge removal process in a single traverse over the substrate so as to cover the entire edge of the substrate.

In one specific embodiment of a tandem junction silicon solar panel where the film stack to be removed from the periphery region 210 of the substrate 202 is composed of a TCO layer of SnO₂ at a thickness of about 1 μm, a silicon-containing film stack at a thickness of about 2 μm, and a metal back contact at a thickness of about 0.2 μm, a target film stack (i.e., the metal back contact and the silicon-containing film stack) is removed from a periphery region 210 of the substrate 202 during a first scan of laser pulses delivered at a first energy density of about 15 mJ/mm² to about 75 mJ/mm², for example, about 25 mJ/mm², and a duration in a range of about 1 nsec to about 3000 nsec, for example, about 35 nsec. Once the target film stack is removed, the TCO layer is removed from the periphery region 210 of the substrate 202 during a second scan of laser pulses delivered at a second energy density of about 45 mJ/mm² to about 120 mJ/mm², for example, about 69 mJ/mm², and a duration in a range of about 1 nsec to about 3000 nsec, for example, about 35 nsec. In one example, the first scan of laser pulses may be delivered by directing a series of sequential laser pulses at a spot overlap of about 2% to about 15%, such as about 5% spot overlap, a line overlap of about 5% to about 15%, such as about 10% line overlap, and a segment overlap of about 15% to about 45%, such as about 30% segment overlap; and the second scan of laser pulses may be delivered by directing a series of sequential laser pulses at a spot overlap of about 10% to about 30%, such as 20% spot overlap, a line overlap of about 5% to about 20%, such as about 10% line overlap, and a segment overlap of about 15% to about 45%, such as about 30% segment overlap.

While not discussed here, it is contemplated that the wave electromagnetic radiation module 306, the substrate 202, or a combination thereof may be moved in a simple rectangular pattern, a zig-zag pattern, a serpentine pattern, or any desired pattern that would result in the above-mentioned overlapping spots, lines, or segments of radiation covering the periphery region 210 of the substrate 202 to be ablated off. Suitable examples regarding various scribing movement are disclosed in detail by US Patent Publication No. 2009/0255911, filed Apr. 10, 2009 by Krishnaswani et al, titled “Laser Scribing Platform and Hybrid Writing Strategy”, which is commonly owned by Applied Materials and which is incorporated herein by reference.

One of ordinary skill in the art will appreciate that the power level of the inventive two-scan process may vary depending upon the film stack configuration, parameters such as layer thickness, layer doping, or layer reflectivity, and process regime provided by the laser. While a two-scan process is discussed, the laser edge removal process may be repeated as many times as necessary to properly cover the entire edge of the substrate. Multiple scanning with gradually increased/decreased laser power is also contemplated depending upon application. Similarly, the frequency, scan speed, and output current of the laser may be adjusted during a laser edge removal process in order to control the overlap area. The amount of the wave electromagnetic radiation module may also affect the number of scanning passes required to process the periphery region. For example, if there are multiple laser scanning devices available in the system to ablate off one of these segments, the substrate 202 can make fewer passes through the module 306.

FIG. 4 depicts a cross sectional view of the substrate 202 after the laser edge removal process is performed. After the laser edge removal process is complete, the films previously located at the periphery region 210 of the substrate 202 are removed. Optionally, a portion of the substrate 202 may also be removed, for example, a depth 402 between about 20 μm and about 40 μm of the substrate surface can be removed. Thus, improved methods for removing one or more film stacks disposed at a substrate edge are provided. The multi-pass laser edge removal processes according to the present invention advantageously increase clearness of the solar cell devices and accuracy of removing a film stack at a periphery region along the side of a substrate without having issues with residue powders or formation of unwanted alloys before they can be removed, thereby providing a good seal surface for the substrate to facilitate subsequent bonding and packaging processes.

While the foregoing is directed to embodiments of the present invention, other and further embodiments of the invention may be devised without departing from the basic scope thereof, and the scope thereof is determined by the claims that follow.

What is claimed is:

1. A method for processing solar cell devices on a substrate, comprising:
providing a substrate having a film stack deposited thereon, the film stack comprising a transparent conductive layer, a silicon-containing layer, and an electrically conductive layer;
removing the electrically conductive layer and the silicon-containing layer formed on a periphery region along a side of the substrate using an electromagnetic radiation delivered at a first energy level; and
removing the transparent conductive layer formed on the periphery region along the side of the substrate using electromagnetic radiation delivered at a second energy level that is higher than the first energy level.

2. The method of claim 1, wherein the electromagnetic radiation is directed through the substrate from the bottom to a desired location in one or more of the layers to be removed.

3. The method of claim 1, wherein the electromagnetic radiation comprises an infrared (IR) laser beam, Nd:YAG laser beam, Nd:YVO₄ laser beam, crystalline disk laser, fiber laser, or the like.

4. The method of claim 1, wherein the electromagnetic radiation used to remove the electrically conductive layer and the silicon-containing layer is delivered at an energy density of about 15 mJ/mm² to about 75 mJ/mm².

5. The method of claim 1, wherein the electromagnetic radiation used to remove the transparent conductive layer is delivered at an energy density of about 45 mJ/mm² to about 120 mJ/mm².

6. The method of claim 4, wherein the electromagnetic radiation used to remove the electrically conductive layer and the silicon-containing layer is delivered by directing a series of sequential laser pulses at a spot overlap of about 2% to about 15%, a line overlap of about 5% to about 15%, and a segment overlap of about 15 to about 45%.

7. The method of claim 5, wherein the electromagnetic radiation used to remove the transparent conductive layer is delivered by directing a series of sequential laser pulses at a spot overlap of about 10% to about 30%, a line overlap of about 5% to about 20%, and a segment overlap of about 15% to about 45%.

8. The method of claim 1, wherein the silicon-containing layer is a film stack comprising a p-type silicon containing layer, a n-type silicon containing layer, and an intrinsic type silicon containing layer sandwiched between the p-type and n-type silicon containing layers.

9. The method of claim 1, wherein the electrically conductive layer comprises a material selected from the group consisting of Al, Ag, Ti, Cr, Au, Cu, Pt, alloys thereof, and combinations thereof.

10. The method of claim 1, wherein the transparent conductive layer comprises a zinc containing material, an aluminum containing material, a tin containing material, an ITO containing material, or alloys thereof.

11. A method for processing solar cell devices on a substrate, comprising:
providing a substrate having a transparent conductive layer and a film stack deposited over the transparent conductive layer, the film stack comprising one or more silicon-containing layers and an electrically conductive layer;
removing the film stack from a periphery region along a side of the substrate during a first scan of an electromagnetic radiation line delivered at a first power level; and
removing the transparent conductive layer from the periphery region along the side of the substrate during a second scan of the electromagnetic radiation line delivered at a second power level that is different from the first power level.

12. The method of claim 11, wherein the first power level is lower than the second power level.

13. The method of claim 11, wherein the electromagnetic radiation line is delivered by directing a series of sequential laser pulses.

14. The method of claim 11, wherein the electromagnetic radiation line and the substrate are moved relative to each other to process the periphery region of the substrate to be removed.

15. The method of claim 13, wherein the electromagnetic radiation used to remove the film stack is delivered at a spot overlap of about 2% to about 15%, a line overlap of about 5% to about 15%, and a segment overlap of about 15 to about 45%.

16. The method of claim 13, wherein the electromagnetic radiation used to remove the transparent conductive layer is delivered at a spot overlap of about 10% to about 30%, a line overlap of about 5% to about 20%, and a segment overlap of about 15% to about 45%.

17. A method for processing solar cell devices on a substrate, comprising:
providing a substrate having a transparent conductive layer and a film stack sequentially deposited thereon, the film stack comprising one or more silicon-containing layers and an electrically conductive layer;
directing a series of sequential laser pulses delivered at a first pulse energy across a periphery region along a side of the substrate to remove the film stack; and
directing a series of sequential laser pulses delivered at a second pulse energy across the periphery region along the side of the substrate to remove the transparent conductive layer, wherein first pulse energy is lower than the second pulse energy.

18. The method of claim 17, wherein the series of sequential laser pulses are partially overlapped to provide a laser ablating segment covering at least a portion of the periphery region.

19. The method of claim 18, wherein the laser ablating segment is repeatedly applied onto the periphery region along the side of the substrate in a single traverse over the substrate.

20. The method of claim 19, wherein the laser ablating segment are repeated at a segment overlap of about 15 to about 45%.
